(19) United States
(12) Patent Application Publication
(10) Pub. No.: US 2021/0210524 A1
(43) Pub. Date: Jul. 8, 2021

(54) THIN FILM TRANSISTOR AND MANUFACTURING METHOD FOR THIN FILM TRANSISTOR

(71) Applicant: Japan Display Inc., Tokyo (JP)

(72) Inventors: Tatsuya TODA, Minato-ku (JP); Masashi TSUBUKU, Minato-ku (JP)

(73) Assignee: Japan Display Inc., Tokyo (JP)

(21) Appl. No.: 17/209,376

(22) Filed: Mar. 23, 2021

Related U.S. Application Data
(63) Continuation of application No. PCT/JP2019/030205, filed on Aug. 1, 2019.

(30) Foreign Application Priority Data
Sep. 28, 2018 (JP) 2018-184114

(51) Int. Cl. H01L 27/12; H01L 29/24; H01L 29/45; H01L 29/786; H01L 21/02; H01L 21/4763; H01L 29/66

(52) U.S. Cl. CPC H01L 27/1248; H01L 27/1225; H01L 29/247; H01L 29/45; H01L 29/78693; H01L 27/3262; H01L 21/02565; H01L 21/02592; H01L 21/47635; H01L 29/66969; H01L 27/127

(57) ABSTRACT

To reduce degradation of characteristics and reliability of a transistor including an oxide semiconductor as an active layer. A thin film transistor comprising: an active layer formed of an oxide semiconductor including at least indium and gallium; an electrode layer including an aluminum layer and partially formed on the active layer; and an interlayer insulating layer formed on the active layer, wherein a peak value of chlorine concentration at an interface between the interlayer insulating layer and the active layer is equal to or less than 2.0×10¹⁹ [atoms/cm³], and a peak value of aluminum concentration at an interface between the interlayer insulating layer and the active layer is equal to or less than 1.0×10²⁰ [atoms/cm³].

### CROSS-REFERENCE TO RELATED APPLICATION

The present application is Bypass Continuation of International Application No. PCT/JP2019/030205, filed on Aug. 1, 2019, which claims priority from Japanese Application No. JP2018-184114 filed on Sep. 28, 2018. The contents of these applications are hereby incorporated by reference into this application.

### BACK GROUND OF THE INVENTION

### 1. Field of the Invention

The present invention relates to a thin film transistor and a manufacturing method for the thin film transistor.

### 2. Description of the Related Art

JP2017-46002A discloses that a semiconductor device having a bottom-gate transistor, in which an insulating layer functioning as a channel protective film is provided on an oxide semiconductor film, removes impurities after forming an insulating layer provided in contact with the oxide semiconductor film and/or a source electrode layer and a drain electrode layer, thereby preventing elements contained in etching gas from remaining as impurities on the surface of the oxide semiconductor film. JP2017-46002A discloses that, as the impurity concentration on the surface of the oxide semiconductor film, chlorine concentration is 5×10¹⁸ atoms/cm³ or less, preferably 1×10¹⁸ atoms/cm³ or less.

Saito, S., Sugita, K., Tonotani, J., & Yamage, M. (2002), Formation of ammonium salts and their effects on controlling pattern geometry in the reactive ion etching process for fabricating aluminum wiring and polysilicon gate, Japanese Journal of Applied Physics, 41, 2220-2224 (Non-Patent Literature 1) discloses adding N₂ gas during dry etching of aluminum wiring with BCl and Cl₂ to generate ammonium salts and depositing the generated ammonium salts as protective layers on the side walls of the aluminum wiring, thereby controlling side etching. Table II in that document shows that adding N₂ to the etching gas significantly increases the carbon concentration in the deposit on the surface of the silicon piece.

### SUMMARY OF THE INVENTION

In TAOS-TFT (Transparent Amorphous Oxide Semiconductor-Thin Film Transistor) in which an oxide semiconductor, such as IGO and IGZO, containing group 13 elements, such as indium and gallium, is used as an active layer, a basic exfoliating agent is used to exfoliate a resist film when a metal electrode is patterned. At this time, when aluminum or a laminated metal film containing aluminum is selected as a material of the metal electrode, aluminum is corroded by the exfoliating agent. For this reason, when a titanium-aluminum-titanium laminated film is selected as the material of the metal electrode, for example, corrosion may progress from the aluminum surface exposed at the end portion of the pattern, resulting in a defect such as a defective pattern shape.

As such, when a N₂ gas is introduced into the etching gas as in the above-mentioned Non-Patent Literature 1, a reaction product containing ammonium salt or carbon, which is considered to originate from the resist film, is also deposited and remains on the surface of the oxide semiconductor layer, which is the active layer. The applicant has found that the degree of residual of this reaction product causes deterioration of characteristics and reliability of the manufactured transistors.

One or more embodiments of the present invention have been conceived in view of the above, and an object thereof is to reduce deterioration of characteristics and reliability of a transistor including an oxide semiconductor as an active layer.

The invention disclosed in the present application in order to solve the above problem has various aspects, and a summary of representative of those aspects is as follows.

A thin film transistor comprising: an active layer formed of an oxide semiconductor including at least indium and gallium; an electrode layer including an aluminum layer and partially formed on the active layer; and an interlayer insulating layer formed on the active layer, wherein a peak value of chlorine concentration at an interface between the interlayer insulating layer and the active layer is equal to or less than 2.0×10¹⁹ [atoms/cm³], and a peak value of aluminum concentration at an interface between the interlayer insulating layer and the active layer is equal to or less than 1.0×10²⁰ [atoms/cm³]. The thin film transistor, wherein a peak value of carbon concentration at an interface between the interlayer insulating layer and the active layer is equal to or less than 1.0×10²⁰ [atoms/cm³].

The thin film transistor, wherein the electrode layer includes a first conductive layer made of a non-aluminum metal, a second conductive layer made of a non-aluminum metal, and an aluminum layer between the first conductive layer and the second conductive layer.

The thin film transistor, further comprising a gate insulating layer that is in contact with the active layer and is provided on an opposite side of the interlayer insulating layer, wherein a peak value of chlorine concentration at an interface between the gate insulating layer and the active layer is equal to or less than 1% of a value of chlorine concentration at an interface between the interlayer insulating layer and the active layer, and a peak value of aluminum concentration at an interface between the gate insulating layer and the active layer is equal to or less than 1% of a value of aluminum concentration at an interface between the interlayer insulating layer and the active layer.

A method for manufacturing a thin film transistor, the method comprising steps of: forming an active layer made of an oxide semiconductor on a substrate, the oxide semiconductor including at least indium and gallium; forming an electrode layer on the active layer, the electrode layer including an aluminum layer; forming a resist layer on the electrode layer; patterning the electrode layer by etching; removing the resist layer; and forming an interlayer insulating layer on the active layer and the electrode layer, wherein a peak value of chlorine concentration at an interface between the interlayer insulating layer and the active layer is equal to or less than 2.0×10¹⁹ [atoms/cm³], and a peak value of aluminum concentration at an interface between the interlayer insulating layer and the active layer is equal to or less than 1.0×10²⁰ [atoms/cm³].

The method, wherein a peak value of carbon concentration at an interface between the interlayer insulating layer and the active layer is equal to or less than 1.0×10²⁰ [atoms/cm³].

The method, further comprising a step of forming a gate insulating layer that is in contact with the active layer and is provided on an opposite side of the interlayer insulating layer, wherein a peak value of chlorine concentration at an interface between the gate insulating layer and the active layer is equal to or less than 1% of a value of chlorine concentration at an interface between the interlayer insulating layer and the active layer, and a peak value of aluminum concentration at an interface between the gate insulating layer and the active layer is equal to or less than 1% of a value of aluminum concentration at an interface between the interlayer insulating layer and the active layer.

The method, wherein when the electrode layer is patterned, removing solution having amine concentration equal to or less than 19 [wt %] is used.

### BRIEF DESCRIPTION OF THE DRAWINGS

FIG. 1 is a diagram for illustrating a cross section of a transistor according to an embodiment of the present invention;

FIG. 2 is an enlarged cross-sectional view of a vicinity of an oxide semiconductor layer of the transistor;

FIG. 3 is a graph of measured drain current values with respect to gate voltages of the transistor manufactured using a remover A as a remover of the resist film;

FIG. 4 is a graph of measured drain current values with respect to gate voltages of the transistor manufactured using a remover B as a remover of the resist film;

FIG. 5 is a graph indicating a result of secondary ion mass spectrometer measurements of indium intensity and chlorine concentration in a depth direction of samples manufactured using the removers A and B;

FIG. 6 is a graph indicating a result of secondary ion mass spectrometer measurements of indium intensity and aluminum concentration in a depth direction of samples manufactured using the removers A and B;

FIG. 7 is a graph indicating a result of secondary ion mass spectrometer measurements of indium intensity and carbon concentration in a depth direction of samples manufactured using the removers A and B;

FIG. 8 is a diagram illustrating a transistor according to an embodiment of the present invention and a display device, which is an OLED, using the transistor and a manufacturing process of the display device; and

FIG. 9 is a diagram illustrating a transistor according to an embodiment of the present invention and a display device, which is an LCD, using the transistor and a manufacturing process of the display device.

### DETAILED DESCRIPTION OF THE INVENTION

Embodiments of the present invention will be described below in detail with reference to the accompanying drawings. The disclosure is merely an example, and appropriate modifications while keeping the gist of the invention that can be easily conceived by those skilled in the art are naturally included in the scope of the invention. The accompanying drawings may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

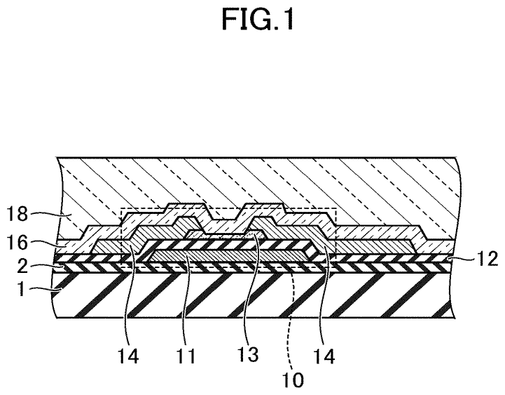

FIG. 1 is a diagram illustrating a cross section of a transistor 10 according to an embodiment of the present invention.

The transistor 10 is a thin film transistor formed on an undercoat layer 2 on a substrate 1 using a photolithographic technique. The substrate 1 is an inorganic or an organic substrate, such as a glass substrate, a quartz substrate, and a resin substrate, and may be rigid or flexible. The undercoat layer 2 is a film that functions as a barrier layer against impurities.

A gate electrode layer 11 is formed on the undercoat layer 2. The gate electrode layer may be formed of a metal or alloy layer, or a conductive metal oxide or other conductive materials, and preferably a low-resistance material is selected. A gate insulating layer 12 is formed on the gate electrode layer 11, and an oxide semiconductor layer 13 is formed on an area that is on the gate insulating layer 12 and overlaps the gate electrode layer 11. The oxide semiconductor layer 13 is an active layer of the transistor 10, and a metal oxide containing at least indium and gallium in the group 13 elements. In the present embodiment, the oxide semiconductor layer 13 is a transparent semiconductor made of oxides of indium, gallium, and zinc known as IGZO.

An electrode layer 14 is formed on the oxide semiconductor layer 13 and the gate insulating layer 12 such that a part of the electrode layer 14 is in contact with the oxide semiconductor layer 13. The electrode layer 14 has a shape of a source electrode and a drain electrode by patterning, and the source electrode and the drain electrode disposed at a predetermined distance without being in contact with each other on the oxide semiconductor layer 13. As such, on the oxide semiconductor layer 13, there is a portion that is not covered by the electrode layer 14. The electrode layer 14 may be a single layer or a multilayer, and includes at least an aluminum layer. In this embodiment, a three-layer structure is formed in which an aluminum layer is sandwiched between two titanium layers provided in an upper layer and a lower layer.

An interlayer insulating layer 16 and a flattening layer 18 are formed on the oxide semiconductor layer 13 and the electrode layer 14. The transistor 10 is thus formed on the substrate 1. Depending on the application of the transistor 10, a through hole penetrating the flattening layer 18 and the interlayer insulating layer 16 is further formed as appropriate so that the electrode layer 14 is connected to the appropriate electrical circuit formed on the flattening layer 18. A device having the transistor 10 is thus formed. Examples of such a device include displays such as an LCD and an OLED.

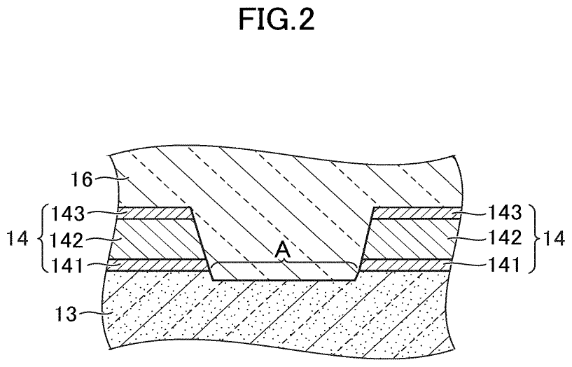

FIG. 2 is an enlarged cross-sectional view of the vicinity of the oxide semiconductor layer 13 of the transistor 10. The electrode layer 14 is formed on the upper surface of the oxide semiconductor layer 13, and the oxide semiconductor layer 13 is exposed upward so as to be sandwiched by the electrode layers 14 and form an area A in directly contact with the interlayer insulating layer 16. The electrode layer 14 has a first conductive layer 141 made of a non-aluminum metal, which is formed in contact with the oxide semiconductor layer 13, and an aluminum layer 142 sandwiched between second conductive layers 143 also made of a non-aluminum metal. In the present embodiment, both the first conductive layer 141 and the second conductive layer 142 are titanium. The aluminum layer 142 is aluminum alone, but may be an alloy containing aluminum. Further, a conductive layer other than the first conductive layer 141, the aluminum layer 142, and the second conductive layer 143 may be additionally provided. In any case, the aluminum layer 142 is exposed to the interlayer insulating layer 16 at the end surface of the electrode layer 14.

The present embodiment features that the peak value of the chlorine concentration in the area A at the interface between the interlayer insulating layer 16 and the oxide semiconductor layer 13, which is an active layer, is 2.0×10¹⁹ [atoms/cm³] or less, the peak value of the aluminum concentration is 1.0×10²⁰ [atoms/cm³] or less, and additionally, the peak value of the carbon concentration is 1.0×10²⁰ [atoms/cm³] or less. Such features will be described below. The technical meaning of the “interface” here will be described later.

In the manufacturing process of the transistor 10, the electrode layer 14 is formed by etching a metal layer formed on the oxide semiconductor layer 13. The etching method is not particularly limited. Here, the metal layer is removed by dry etching until the surface of the oxide semiconductor layer 13 in the area A is exposed. The portion to be the electrode layer 14 is protected by the resist film where the metal layer is not removed and remains.

At this time, impurities such as etching gas are adhered to the surface of the area A of the oxide semiconductor layer 13. At this time, if nitrogen gas is introduced into the etching gas containing chlorine or chloride, as reaction products, ammonium salts such as NH₄AlCl₄ and NH₄Cl or carbon compounds derived from a resist film adhere as impurities. Such impurities also adhere to the end surface of the electrode layer 14, and function as a protective layer of the aluminum layer 142 when the resist film is removed and cleaned. Such features are as described in Non-Patent Literature 1.

A considerable part of such impurities is washed away when removing the resist film protecting the electrode layer 14, and a part of the impurities remains as residual chlorine. At this time, if a basic exfoliating agent is used as a remover of the resist film, the residual amount of such impurities varies depending on the selection of the remover.

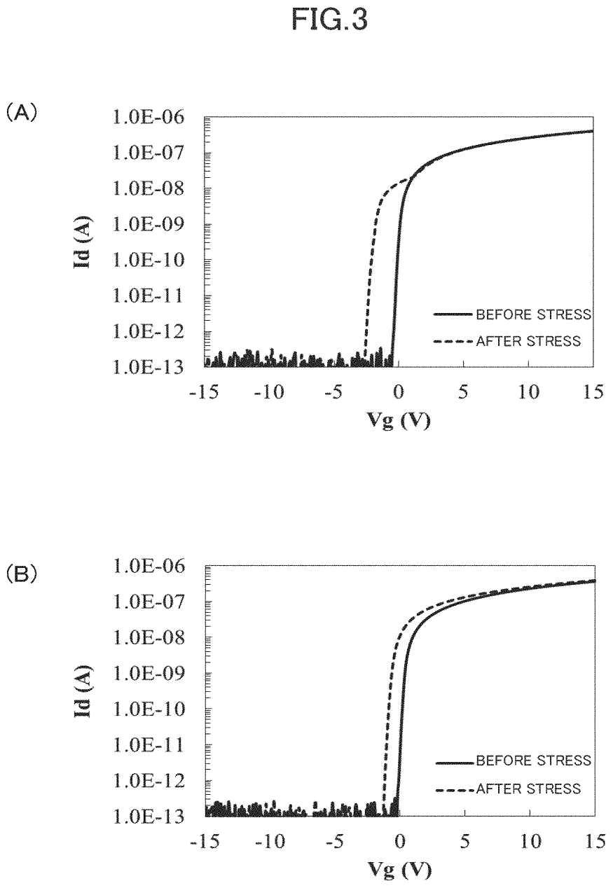

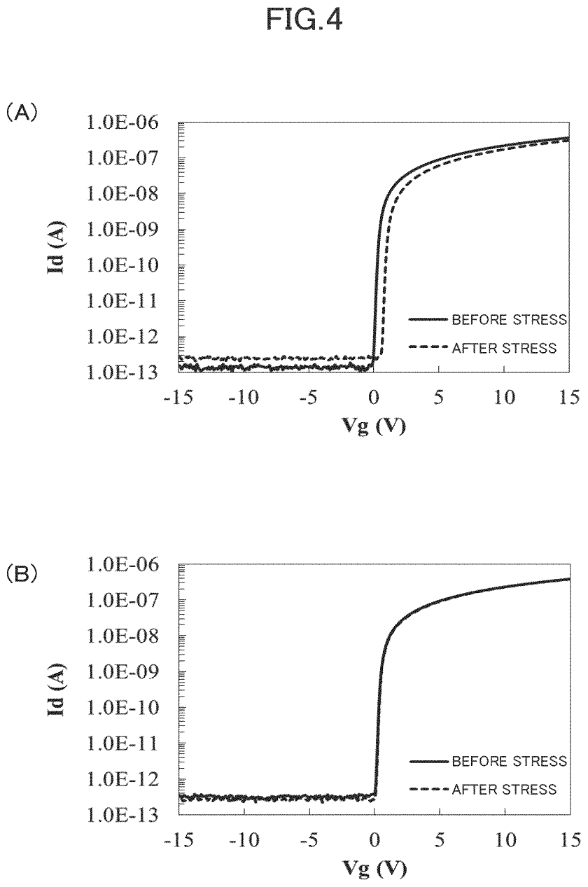

The applicant has found that the residual amount of such impurities causes deterioration of the properties and reliability of the manufactured transistor 10. FIGS. 3 and 4 are graphs of measured drain current values with respect to gate voltages of the transistor 10 manufactured using different removers A and B as the removers of the resist film. In FIG. 3, the graph shows the measured values for the sample using the remover A, and in FIG. 4, the graph shows the measured values for the sample using the remover B.

Both of the removers A and B are basic liquid agents, and their properties are as shown in Table 1 below.

TABLE 1

| | REMOVER A | REMOVER B |
|---|---|---|
| pH | 10.5 | 11.4 |
| AMINE | 4-6 | 19 |
| CONCENTRATION (wt. %) | | |

Further, in FIGS. 3 and 4, the value shown by a solid line is a measurement value immediately after manufacture, and the value shown by a broken line shows a measurement value after a positive or negative load is applied to the gate voltage. FIGS. 3A and 4A show measured results before and after PBTS (Positive Bias Temperature Stress) test, and FIGS. 3B and 4B show measurement results before and after NBTS (Negative Bias Temperature Stress) test. The application conditions of PBTS and NBTS are as shown in Table 2 below.

TABLE 2

| | GATE VOLTAGE | TEMPERATURE | APPLICATION TIME |
|---|---|---|---|
| PBTS | 30 V | 60° C. | 1 hr |
| NBTS | −30 V | 60° C. | 1 hr |

As shown in FIG. 3, the sample manufactured using the remover A shows that the gate threshold voltage after the load is applied (the gate voltage at which the drain current begins to flow) is deviated in the negative direction in both of PBTS and NBTS. This indicates that the characteristics of the transistor 10 has deteriorated. In contrast, as shown in FIG. 4, the sample manufactured using the remover B shows that the gate threshold voltage after the load is applied (the gate voltage at which the drain current begins to flow) is not deviated in the negative direction in both of PBTS and NBTS. In the case of PBTS, the gate threshold voltage after the load is applied is slightly deviated in the positive direction. However, such a change is acceptable as a product property because the change is maintained as a slight negative voltage and does not cause drain current leakage when the gate voltage is applied during standby.

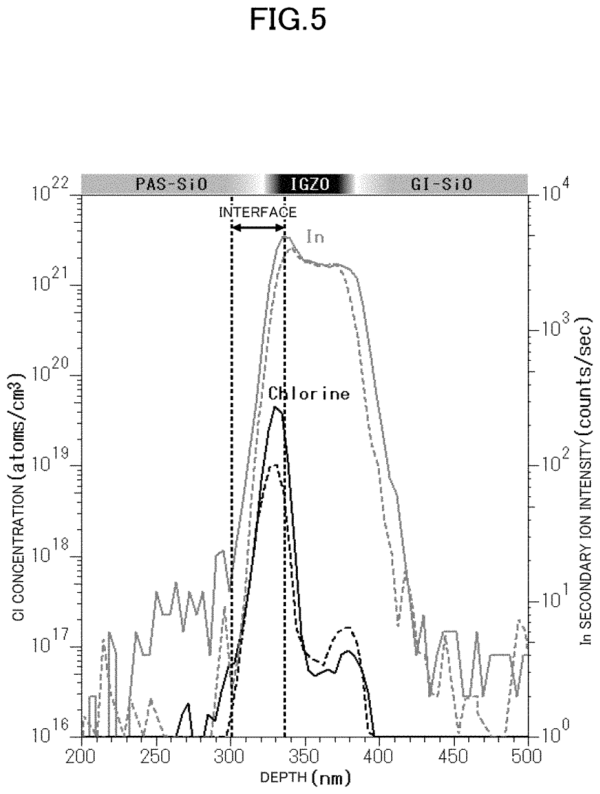

FIGS. 5 to 7 are graphs indicating the results of secondary ion mass spectrometer measurements of the indium intensity and the concentration of chlorine, aluminum or carbon in the depth direction of the samples manufactured using the removers A and B.

The graph in FIG. 5 shows the secondary ion intensity (unit: number of detections per second) of indium and the chlorine concentration (unit: number of atoms per square centimeter). The solid line shows the measurement results of the sample manufactured using the remover A, and the dashed line shows the sample manufactured using the remover B. The chlorine concentration is obtained by converting the secondary ion intensity of chlorine measured by the secondary ion mass spectrometer. The horizontal axis shows the position in the depth direction of the transistor 10 used as a measurement sample. In the graph, the left direction is the upper direction of the sample, and the right direction is the lower direction of the sample. As shown in the top of the graph, “PAS-SiO” indicates a range corresponding to the interlayer insulating layer 16, “IGZO” indicates a range corresponding to the oxide semiconductor layer 13, and “GI-SiO” indicates a range corresponding to the gate insulating layer 12 in general.

As is apparent from the graph, the chlorine concentration shows a peak value in the range in which the composition of the sample is changed from the interlayer insulating layer 16 to the oxide semiconductor layer 13, i.e., at the interface between the interlayer insulating layer 16 and the oxide semiconductor layer 13. The peak value of the sample manufactured using the remover A is approximately 4.6×10¹⁹ [atoms/cm³], and the peak value of the sample manufactured using the remover B is approximately 1.0×10¹⁹ [atoms/cm³]. Such chlorine is considered to be mainly derived from ammonium salt, which is an impurity adhered to the surface of the oxide semiconductor layer 13 in the manufacturing process of the sample, and thus it is considered that the remover B has a higher ability to clean impurities than the remover A and thus the residual chlorine concentration is lowered.

The interface may be determined in any range if it reasonably indicates a range in which the composition of the sample changes from the interlayer insulating layer 16 to the oxide semiconductor layer 13, although in this specification, the interface indicates a range in which the secondary ion intensity of any of the group 13 elements forming the oxide semiconductor layer 13 monotonically increases in the depth direction of the sample. According to this definition, in FIG. 5, the range of the interface between the interlayer insulating layer 16 and the oxide semiconductor layer 13 is indicated as the range in which the secondary ion intensity of indium monotonically increases.

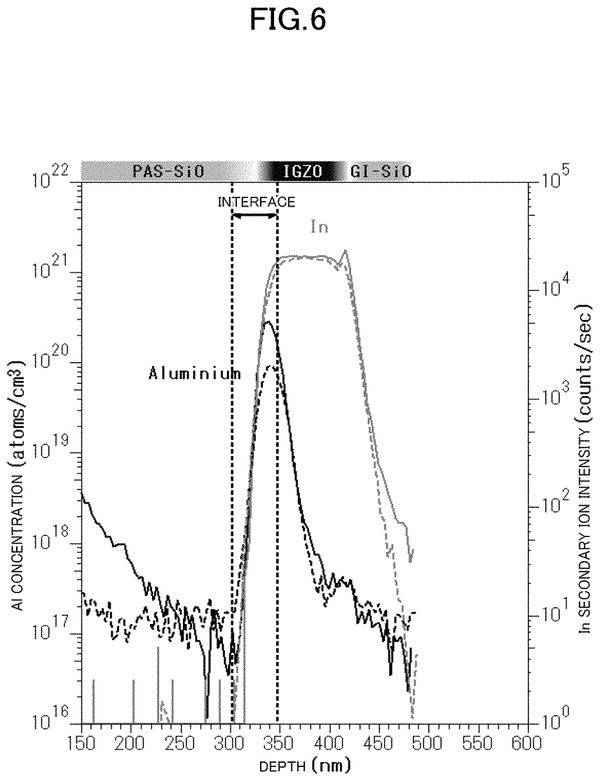

The graph in FIG. 6 shows the secondary ion intensity of indium and the aluminum concentration. Similarly to FIG. 5, the solid line is a measurement result of a sample manufactured using the remover A, and the dashed line is a measurement result of the sample manufactured using the remover B. In the graph, the aluminum concentration also shows a peak value at the interface between the interlayer insulating layer 16 and the oxide semiconductor layer 13. The peak value of the sample manufactured using the remover A is approximately 2.9×10²⁰ [atoms/cm³], and the peak value of the sample manufactured using the remover B is approximately 9.4×10¹⁹ [atoms/cm³]. Such aluminum is considered to be an impurity derived from the aluminum layer 142 of the electrode layer 14 in the manufacturing process of the sample, and it is also considered that the remover B has a higher ability to clean impurities than the remover A and thus the residual aluminum concentration is lowered.

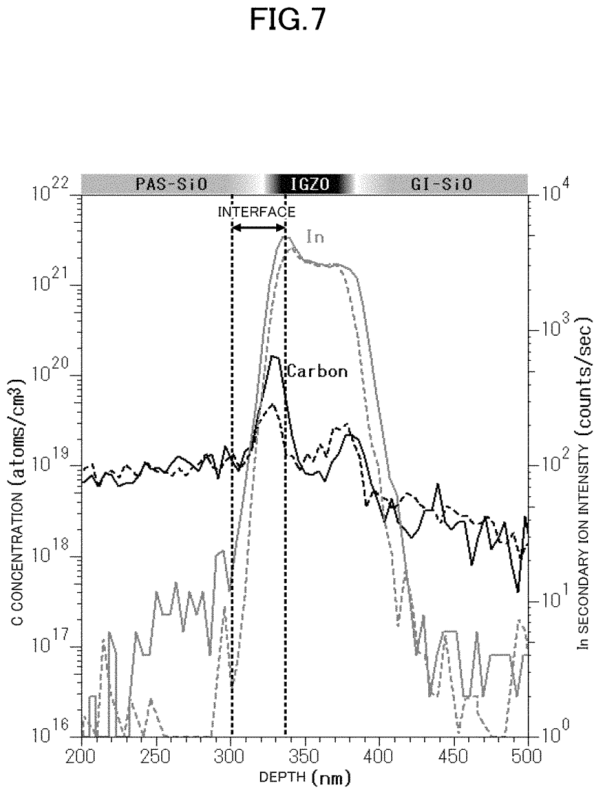

The graph in FIG. 7 shows the secondary ion intensity of indium and the carbon concentration. Similarly to FIGS. 5 and 6, the solid line is a measurement result of a sample manufactured using the remover A, and the dashed line is a measurement result of the sample manufactured using the remover B. In the graph, the carbon concentration also shows a peak value at the interface between the interlayer insulating layer 16 and the oxide semiconductor layer 13. The peak value of the sample manufactured using the remover A is approximately 1.5×10²⁰ [atoms/cm³], and the peak value of the sample manufactured using the remover B is approximately 5.0×10¹⁹ [atoms/cm³]. Such carbon is considered to be an impurity derived from the resist layer in the manufacturing process of the sample, and it is also considered that the remover B has a higher ability to clean impurities than the remover A and thus the residual carbon concentration is lowered.

Table 3 summarizes the above results.

TABLE 3

| | CHLORINE CONCENTRATION | ALUMINUM CONCENTRATION | CARBON CONCENTRATION |
|---|---|---|---|
| REMOVER A | 4.6 × 10¹⁹ | 2.9 × 10²⁰ | 1.5 × 10²⁰ |
| REMOVER B | 1.0 × 10¹⁹ | 9.4 × 10¹⁹ | 5.0 × 10¹⁹ |

*Each indicates the peak value at the interface. Units are [atoms/cm³]

From the above, it is seen that deterioration in the characteristics and reliability of the transistor can be reduced in the sample using the remover B, which has higher ability to clean impurities on the oxide semiconductor layer 13. As such, for the residual concentration of the impurity to obtain the similar result, it is considered that the peak value of the chlorine concentration at the interface between the interlayer insulating layer 16 and the oxide semiconductor layer 13 may preferably be 2.0×10¹⁹ [atoms/cm³] or less, and the peak value of the aluminum concentration may preferably be 1.0×10²⁰ [atoms/cm³] or less. Further, it is considered that the peak value of the carbon concentration at the interface between the interlayer insulating layer 16 and the oxide semiconductor layer 13 may preferably be 1.0×10²⁰ [atoms/cm³] or less.

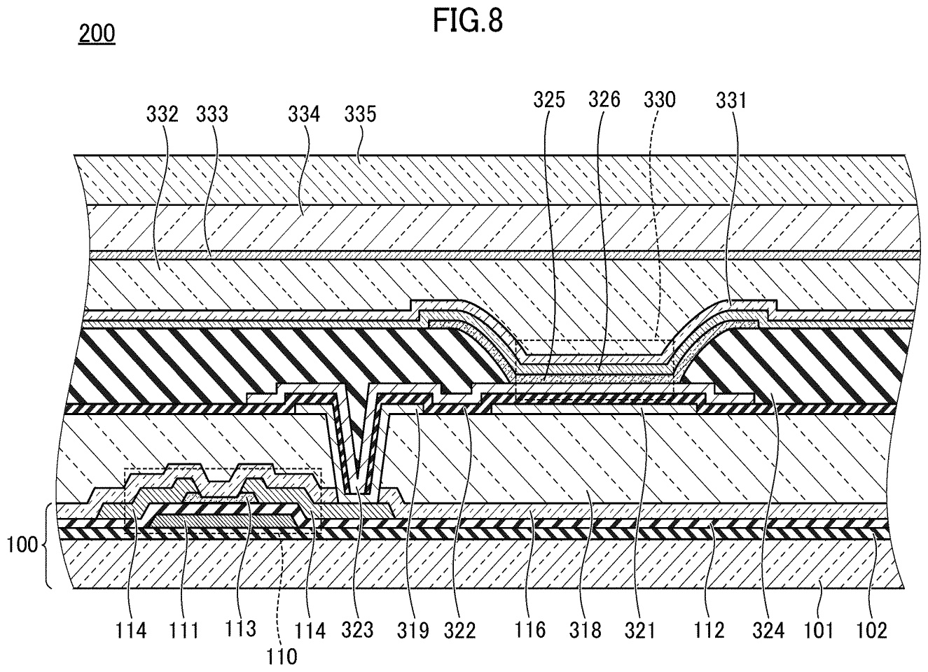

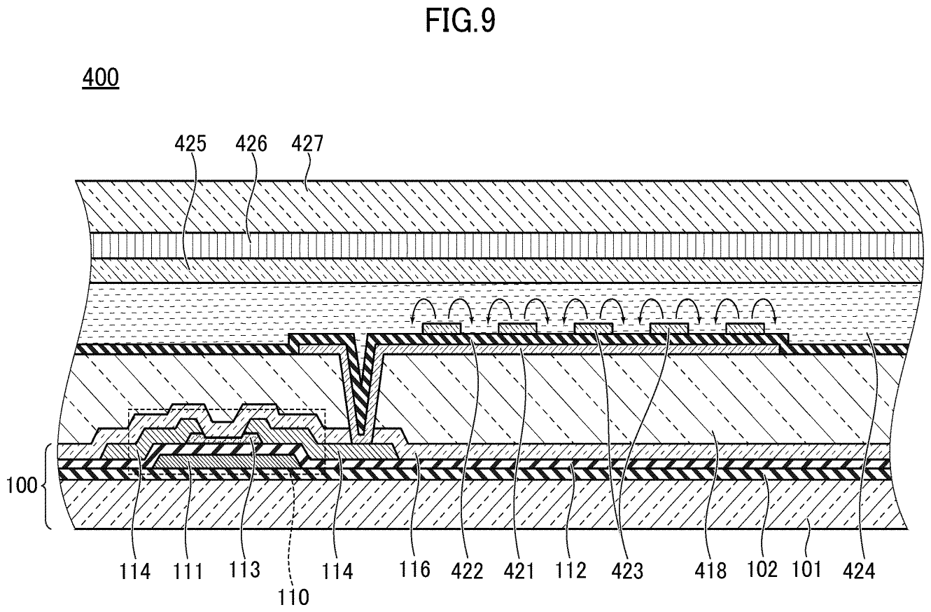

Next, referring to FIGS. 8 and 9, a transistor according to an embodiment of the present invention and a manufacturing process of a display device using the transistor will be described.

### Manufacture of Transistor 110 (FIGS. 8 and 9)

A substrate 101 is prepared. Examples of the substrate 101 include a glass substrate, a quartz substrate, and a resin substrate. A resin substrate provides flexibility to the substrate 101.

An undercoat layer 102 is formed on the substrate 101. One of the purposes of providing the undercoat layer 102 is to serve as a barrier film for preventing an impurity contained in the substrate 101 or an impurity entered from the back surface of the substrate 101. In this case, the undercoat layer 102 may be formed of silicon nitride, silicon nitride oxide, aluminum nitride, aluminum nitride oxide, aluminum oxide, which have excellent barrier properties, or a laminated film containing these materials.

A gate electrode layer 111 is formed on the undercoat. The gate electrode layer 111 may use a metal such as aluminum, titanium, chromium, molybdenum, tantalum, and tungsten, or an alloy containing these metals. The gate electrode of the transistor may use not only the metal materials described above but also a transparent conductive material, such as ITO and IZO. In a case where such a layer is used not only as the gate electrode of the transistor but also as a conductive layer for forming surrounding wiring, it is more preferable to use the metal material described above, since low resistance is required. The gate electrode layer 111 may be formed to have a thickness of about 50 nm to 700 nm, preferably 100 nm to 500 nm.

A gate insulating layer 112 is formed on the gate electrode layer 111. The gate insulating layer 112 may be formed of silicon nitride, silicon nitride oxide, silicon oxide, or a laminated film containing these materials. The gate insulating layer 112 may be formed to have a thickness of about 50 nm to 700 nm, preferably about 100 nm to 500 nm.

An oxide semiconductor layer 113 is formed on the gate insulating layer 112 and in an area to overlap with the gate electrode layer 111 formed previously. The oxide semiconductor layer 113 is typically a metal oxide containing a group 13 element such as indium and gallium, and specifically, IGO and IGZO. The oxide semiconductor layer 113 may contain other elements, for example, tin belonging to group 14 elements, and titanium and zirconium belonging to group 4 elements. The oxide semiconductor layer 113 may be formed to have a thickness of about 5 nm to 100 nm, preferably 5 nm to 60 nm.

The crystallinity of the oxide semiconductor layer 113 is not particularly limited, and may be any of a single crystal, a polycrystal, and a microcrystal. Alternatively, the oxide semiconductor layer 113 may be amorphous. The characteristics of the oxide semiconductor layer 113 may preferably include few crystal defects, such as oxygen deficiency, and a low hydrogen content concentration. This is because hydrogen contained in the oxide semiconductor layer 113 functions as a donor and induces a current leakage of the transistor.

An electrode layer 114 is formed in contact with the oxide semiconductor layer 113. As shown, the electrode layer 114 is formed as a source electrode and a drain electrode. Similarly to the gate electrode layer 111, the electrode layer 114 may use a metal, such as aluminum, titanium, chromium, molybdenum, tantalum, and tungsten, or an alloy containing these metals, and includes at least aluminum or an alloy containing aluminum. The electrode layer 114 is formed in contact with the oxide semiconductor layer 113, and thus, the surface of the electrode layer 114 in contact with the oxide semiconductor layer 113 may preferably be formed of a material having ohmic resistive properties at the connection part thereof. In the present embodiment, as described above, the electrode layer 114 is formed as a laminate in which the aluminum layer is sandwiched between the two titanium layers. The electrode layer 114 may be formed to have a thickness of about 50 nm to 1 μm, preferably 300 nm to 700 nm.

The electrode layer 114 is patterned by etching. Any suitable etching method may be selected depending on conditions. In the present embodiment, a photosensitive resist film is formed on the wiring layer, and then a mask pattern is formed by photolithography. Subsequently, an excess metal film of the wiring layer is removed by dry etching using etching gas. At this time, a part of the surface of the oxide semiconductor layer 113 is slightly etched, and chlorine contained in the etching gas and the reaction product at the time of etching adhere to the surface of the oxide semiconductor layer 113 and the end surface of the electrode layer 114 as impurities. Subsequently, the resist film on the wiring layer is removed using a removing solution. At this time, the impurity adhered to the oxide semiconductor layer 13 is also cleaned and removed, where the peak value of the chlorine concentration at the interface between the interlayer insulating layer 16 and the oxide semiconductor layer 13 is 2.0×10¹⁹ [atoms/cm³] or less, the peak value of the aluminum concentration is 1.0×10²⁰ [atoms/cm³] or less, and the peak value of the carbon concentration at the interface between the interlayer insulating layer 16 and the oxide semiconductor layer 13 is 1.0×10²⁰ [atoms/cm³] or less.

With such patterning, the electrode layer 114 is formed as a source electrode and a drain electrode. In the above steps, the transistor 110 and the surrounding wiring layer (not shown) are formed.

### Manufacture of Display Device 200 (FIG. 8)

After the transistor 110 is formed, an interlayer insulating layer 116 overlying the transistor 110 and a flattening layer 318 are formed. The interlayer insulating layer 116 is partially in contact with the oxide semiconductor layer 113, and thus, similarly to the undercoat layer 102 and the gate insulating layer 112, may be formed of silicon nitride, silicon nitride oxide, and silicon oxide, or a laminated film containing these materials. The interlayer insulating layer 116 may be formed to have a thickness of about 50 nm to 700 nm, preferably 100 nm to 500 nm. One of the purposes to provide the flattening layer 318 is to reduce the unevenness of the transistor 110, for example. The flattening layer 318 may use a thermosetting or a photocuring organic resin. The flattening layer 318 may be formed to have a thickness about 300 nm to 2 μm, preferably 500 nm to 1 μm.

A contact hole reaching the electrode layer 114 is formed in the interlayer insulating layer 116 and the flattening layer 318. A pixel electrode 323 is then formed to be electrically connected to the drain electrode of the electrode layer 114 through the contact hole. As shown in FIG. 8, after the contact hole is formed, a conductive layer 319 may be formed so as to cover the contact hole, and a conductive layer 321 may be formed at the same time. One of the purposes to provide the conductive layer 319 is to improve the connection between the drain electrode of the electrode layer 114 and the pixel electrode 323. The conductive layer 321 is provided so as to overlap with the pixel electrode 323 via a capacitance insulating layer 322 and to form a capacitance at the overlapped portion.

Here, the pixel electrode 323 functions as an anode of the organic EL element 330. In a case where the display device 200 is configured as a top emission type, the pixel electrode 323 is formed as a reflecting electrode. At this time, the pixel electrode 323 is required to have a good surface reflectivity and the work function for functioning as an anode of the organic EL element 330. In order to satisfy these requirements, the pixel electrode 323 may be formed as a laminated film of highly reflective aluminum and silver having the outermost surface made of an indium-based oxide conductive layer, such as ITO and IZO. The pixel electrode is may be formed such that a thickness of the reflective layer made of materials such as aluminum and silver is about 50 nm to 300 nm, preferably 100 nm to 200 nm, and the surface layer made of ITO and IZO formed thereon is about 5 nm to 100 nm, preferably 10 nm to 50 nm.

Subsequently, an insulating layer 324 is formed so as to cover the end of the pixel electrode 323 and provide an opening exposing the upper surface of the pixel electrode 323. An area corresponding to the upper surface of the pixel electrode 323 exposed from the insulating layer 324 is to be a light emitting area of the organic EL device later. The insulating layer 324 functions as a member for separating adjacent pixel electrodes 323, and is thus generally referred to as a “partition wall,” “bank,” and “rib.” The insulating layer 324 may be preferably formed to have a flat upper surface and a smooth tapered side wall of the opening portion, and may use a thermosetting or a photocuring organic resin similarly to the flattening layer 318. The insulating layer 324 may be formed to have a thickness of about 300 nm to 2 μm, preferably 500 nm to 1 μm.

An organic layer 325 is formed so as to cover the exposed pixel electrode 323. The organic layer 325 includes at least a light-emitting layer, and functions as a light-emitting part of the organic EL element 330. The organic layer 325 may include charge transport layers, such as a hole injection layer, a hole transport layer, an electron injection layer, and an electron transport layer, in addition to the light-emitting layer, and may further include charge block layers, such as a hole block layer and an electron block layer. The thickness of the organic layer 325 varies depending on the included layers and their optical properties, and may be about 5 nm to 500 nm, preferably 10 nm to 150 nm. In FIG. 8, the organic layer 325 is provided on one pixel electrode 323, but may be continuously formed on a plurality of pixel electrodes 323 and the insulating layer 324.

After the organic layer 325 is formed, a counter electrode 326 is formed. Here, the counter electrode 326 functions as a cathode of the organic EL device 330. When the display device 200 is configured as a top emission type, the counter electrode 326 is formed as a transparent electrode. At this time, the counter electrode 326 is required to have high transmittance that does not interfere with light emission from the organic layer 325 and a work function for functioning as a cathode of the organic EL element 330. In order to satisfy these requirements, the counter electrode 326 may be formed as an indium-based oxide transparent conductive layer, such as ITO and IZO, or a thin film made of magnesium, silver, or an alloy or a compound thereof and having thickness to ensure enough transmittance. When using an indium-based oxide transparent conductive layer, the counter electrode 326 may be formed to have a thickness of about 50 nm to 500 nm, preferably 100 nm to 300 nm, and when using magnesium, silver, or an alloy or a compound thereof, a thickness of about 5 nm to 50 nm, preferably 10 nm to 30 nm. The counter electrode 326 is a common electrode for a plurality of organic EL elements 330, and formed continuously on a plurality of pixel electrodes 323 and the insulating layer 324.

The functions of the organic EL element 330 are easily deteriorated due to penetration of moisture, and thus, a sealing layer is formed. FIG. 8 shows an example of a sealing layer including an inorganic insulating layer 331, an organic insulating layer 332, and an inorganic insulating layer 333. The inorganic insulating layers 331 and 333 may be formed of silicon nitride, silicon nitride oxide, aluminum nitride, aluminum nitride oxide, aluminum oxide, which have excellent barrier properties, or a laminated film containing those materials. The organic insulating layer 332 may use a thermosetting or photocuring organic resin. The sealing layer has a laminate structure of the inorganic insulating layers 331 and 333 and the organic insulating layer 332, thereby preventing seal failures due to particles mixed during the processes. The thickness of the sealing layer may be about 300 nm to 2 μm, preferably 500 nm to 1 μm in the inorganic insulating layers 331 and 333, and about 1 μm to 20 μm, preferably 2 μm to 10 μm in the organic insulating layer 332.

With the steps described above, the display device 200, which is an OLED, is manufactured. As shown in FIG. 8, a counter substrate 335 may be provided on the inorganic insulating layer 333 with an adhesive 334 interposed therebetween. The counter substrate 335 may have functions of a cover glass and a touch sensor, for example.

### Manufacture of Display Device 400 (FIG. 9)

After the transistor 110 is formed, an interlayer insulating layer 116 overlying the transistor 110 and a flattening layer 418 are formed. The interlayer insulating layer 116 is partially in contact with the oxide semiconductor layer 113, and thus, similarly to the undercoat layer 102 and the gate insulating layer 112, may be formed of silicon nitride, silicon nitride oxide, and silicon oxide, or a laminated film containing these materials. The interlayer insulating layer 116 may be formed to have a thickness of about 50 nm to 700 nm, preferably 100 nm to 500 nm. One of the purposes to provide the flattening layer 418 is to reduce the unevenness of the transistor 110, for example. The flattening layer 418 may use a thermosetting or a photocuring organic resin. The flattening layer 418 may be formed to have a thickness of about 300 nm to 2 μm, preferably 500 nm to 1 μm.

A contact hole reaching the electrode layer 114 is formed in the interlayer insulating layer 116 and the flattening layer 418. A pixel electrode 421 is then formed to be electrically connected to the drain electrode of the electrode layer 114 through the contact hole. The pixel electrode 421 may use an indium-based oxide transparent conductive layer, such as ITO and IZO. The pixel electrode 421 may be formed to have a thickness of about 50 nm to 500 nm, preferably 100 nm to 300 nm.

Common electrodes 423 are formed on the pixel electrode 421 with the insulating layer 422 therebetween. Similarly to the pixel electrode 421, the common electrodes 423 may use an indium-based oxide transparent conductive layer, such as ITO and IZO. In FIG. 9, although the common electrodes 423 are illustrated discretely, they are connected to each other when viewed in a plan view and formed in a comb-like or a plate shape having slits. The shapes of the pixel electrode 421 and the common electrode 423 are not limited to this example, and the pixel electrode in a comb-like or a plate shape having slits may be formed on the common electrodes formed in a plate shape with the insulating layer 422 therebetween.

The color filter 426 and the overcoat layer 425 are formed on the counter substrate 427 so as to face the substrate 101, and a liquid crystal layer 424 is provided in the gap therebetween. In the liquid crystal layer 424, the alignment direction of the liquid crystal is controlled by the pixel electrode 421 and the common electrode 423 described above and the lateral electric field applied as indicated by the arrow, and the transmittance of the light beam is controlled.

With the steps described above, the display device 400, which is an LCD, is manufactured.

The display devices 200 and 400 described above can reduce the deterioration of the characteristics and reliability of the transistor 110, in which the pixel electrodes 323 and 421 and the drain electrode of the electrode layer 114 are connected, thereby maintaining a good display performance over a long period of time.

Within the scope of the idea of the present invention, those skilled in the art can come up with various changes and modifications and it will be understood that these changes and modifications also fall into the scope of the present invention. For example, in each of the above-described embodiments, addition, deletion or redesign of a component, or addition, omission or condition change of a process, which are appropriately made by a person skilled in the art, are also included within the scope of the present invention as long as they remain the gist of the present invention.

What is claimed is:

1. A thin film transistor comprising:
an active layer formed of an oxide semiconductor including at least indium and gallium;
an electrode layer including an aluminum layer and partially formed on the active layer; and
an interlayer insulating layer formed on the active layer, wherein
a peak value of chlorine concentration at an interface between the interlayer insulating layer and the active layer is equal to or less than 2.0×10¹⁹ [atoms/cm³], and a peak value of aluminum concentration at an interface between the interlayer insulating layer and the active layer is equal to or less than 1.0×10²⁰ [atoms/cm³].

2. The thin film transistor according to claim 1, wherein
a peak value of carbon concentration at an interface between the interlayer insulating layer and the active layer is equal to or less than 1.0×10²⁰ [atoms/cm³].

3. The thin film transistor according to claim 1, wherein
the electrode layer includes a first conductive layer made of a non-aluminum metal, a second conductive layer made of a non-aluminum metal, and an aluminum layer between the first conductive layer and the second conductive layer.

4. The thin film transistor according to claim 1, further comprising a gate insulating layer that is in contact with the active layer and is provided on an opposite side of the interlayer insulating layer, wherein
a peak value of chlorine concentration at an interface between the gate insulating layer and the active layer is equal to or less than 1% of a value of chlorine concentration at an interface between the interlayer insulating layer and the active layer, and
a peak value of aluminum concentration at an interface between the gate insulating layer and the active layer is equal to or less than 1% of a value of aluminum concentration at an interface between the interlayer insulating layer and the active layer.

5. A method for manufacturing a thin film transistor, the method comprising steps of:
forming an active layer made of an oxide semiconductor on a substrate, the oxide semiconductor including at least indium and gallium;
forming an electrode layer on the active layer, the electrode layer including an aluminum layer;
forming a resist layer on the electrode layer;
patterning the electrode layer by etching;
removing the resist layer; and
forming an interlayer insulating layer on the active layer and the electrode layer, wherein
a peak value of chlorine concentration at an interface between the interlayer insulating layer and the active layer is equal to or less than 2.0×10¹⁹ [atoms/cm³], and a peak value of aluminum concentration at an interface between the interlayer insulating layer and the active layer is equal to or less than 1.0×10²⁰ [atoms/cm³].

6. The method according to claim 5, wherein
a peak value of carbon concentration at an interface between the interlayer insulating layer and the active layer is equal to or less than 1.0×10²⁰ [atoms/cm³].

7. The method according to claim 5, further comprising a step of forming a gate insulating layer that is in contact with the active layer and is provided on an opposite side of the interlayer insulating layer, wherein
a peak value of chlorine concentration at an interface between the gate insulating layer and the active layer is equal to or less than 1% of a value of chlorine concentration at an interface between the interlayer insulating layer and the active layer, and
a peak value of aluminum concentration at an interface between the gate insulating layer and the active layer is equal to or less than 1% of a value of aluminum concentration at an interface between the interlayer insulating layer and the active layer.

8. The method according to claim 5, wherein
when the electrode layer is patterned, removing solution having amine concentration equal to or less than 19 [wt %] is used.
